(19) United States
(12) Patent Application Publication
(10) Pub. No.: US 2023/0125335 A1
(43) Pub. Date: Apr. 27, 2023

(54) LIGHT EMITTING ELECTROCHEMICAL CELLS, ELECTROSTATIC INKS AND METHODS OF MAKING ELECTROSTATIC INKS

(71) Applicant: HEWLETT-PACKARD DEVELOPMENT COMPANY, L.P., Spring, TX (US)

(72) Inventors: Samer Farran, Nes Ziona (IL); Yaron Grinwald, Nes Ziona (IL); Rada Nuchimov, Nes Ziona (IL); Ofir Bros, Nes Ziona (IL)

(21) Appl. No.: 17/913,329

(22) PCT Filed: Apr. 9, 2020
(86) PCT No.: PCT/US2020/027518

§ 371 Date: Sep. 21, 2022

(51) Int. Cl. H10K 50/135; C09K 11/56; C09D 11/52; C09D 11/50; C09D 11/037; C09D 11/107; H10K 71/00

(52) U.S. Cl. CPC H01L 51/5032; C09K 11/565; C09D 11/52; C09D 11/50; C09D 11/037; C09D 11/107; H01L 51/56; H01L 2251/533

(57) ABSTRACT

Herein is described a light-emitting electrochemical cell comprising: a first electrode and a second electrode; a light-emitting layer disposed between the first and second electrodes and comprising a printed electrostatic ink comprising a thermoplastic resin having dispersed therein an electroluminescent material. Also described herein is a method of making an electrostatic ink, the method comprising: providing a carrier fluid (i) in which is dispersed a molten or a dissolved thermoplastic polymer resin and (ii) containing particles of an electroluminescent material suspended therein; effecting precipitation of the polymer resin from the carrier fluid onto the electroluminescent material to form particles comprising the electroluminescent material with a coating comprising the thermoplastic resin in solid form thereon. Also described herein is an electrostatic ink comprising: chargeable particles comprising an electroluminescent material having a coating of a thermoplastic resin thereon.

Electroluminescent devices are devices that light up when an electric current is passed through an electroluminescent component (often a layer between two electrodes, one of which is transparent). Some devices have been made by printing an electroluminescent ink on an electrode. This may be done in an analogue way, e.g. by screen printing. However, analogue printing has its limitations.

### BRIEF DESCRIPTION OF THE FIGURES

FIG. 1 shows an example of a light-emitting electrochemical cell comprising a first electrode 101 and a second electrode 104, which is a transparent electrode, and a light-emitting layer 103 disposed between the first and second electrodes. The light-emitting layer 103 comprises a printed electrostatic ink comprising a thermoplastic resin having dispersed therein an electroluminescent material. Light emitted from the light-emitting layer 103 is shown with arrows pointing down the page, denoted with an ‘L’.

FIG. 2 shows an example of a light-emitting electrochemical cell comprising a first electrode 101 and a second electrode 104, which is a transparent electrode, and a light-emitting layer 103 disposed between the first and second electrodes. In this embodiment, a dielectric insulating layer 102 is disposed between the light-emitting layer, and the first electrode. The second electrode is disposed upon a transparent substrate 105.

FIG. 3 shows an example of a light-emitting electrochemical cell comprising a first electrode 101 and a second electrode 104 and a light-emitting layer 103 disposed between the first and second electrodes. In this embodiment, a dielectric insulating layer 102 is disposed between the light-emitting layer, and the second electrode (instead of between the light-emitting layer and the first electrode as in FIG. 1).

FIG. 4 shows an example of a light-emitting electrochemical cell similar to that shown in FIG. 1, i.e. comprising the first electrode 101 and the second electrode 104, which is a transparent electrode, and the light-emitting layer 103 disposed between the first and second electrodes. In this example, however, an image layer 107 is disposed between the first electrode 101 and the light-emitting layer 103. In an example, the image layer 107 may be a printed layer comprising one or more pigments selected from magenta, cyan, yellow and black. Light emitted from the light-emitting layer 103 is shown with arrows pointing down the page, denoted with an L′.

FIG. 5 shows an example of a light-emitting electrochemical cell, similar to that of FIG. 2, i.e. comprising the first electrode 101 and the second electrode 104, which is a transparent electrode, and a light-emitting layer 103 disposed between the first and second electrodes. In this embodiment, a dielectric insulating layer 102 is disposed between the light-emitting layer, and the first electrode 101. The second electrode 104 is disposed upon a transparent substrate 105. In this example, however, an image layer 107 is disposed between the dielectric insulating layer 102 and the light-emitting layer 103. In an example, the image layer 107 may be a printed layer comprising one or more pigments selected from magenta, cyan, yellow and black. Light emitted from the light-emitting layer 103 is shown with arrows pointing down the page, denoted with an L′.

### DETAILED DESCRIPTION

Before the light-emitting electrochemical cells, inks, compositions, methods and related aspects of the disclosure are disclosed and described, it is to be understood that this disclosure is not restricted to the particular process features and materials disclosed herein because such process features and materials may vary somewhat. It is also to be understood that the terminology used herein is used for the purpose of describing particular examples. The terms are not intended to be limiting because the scope is intended to be limited by the appended claims and equivalents thereof.

It is noted that, as used in this specification and the appended claims, the singular forms “a,” “an,” and “the” include plural referents unless the context clearly dictates otherwise.

As used herein, “liquid carrier”, “carrier liquid”, “carrier,” or “carrier vehicle” refers to the fluid in which components of a liquid electrostatic ink composition (also termed a liquid electrophotographic ink) can be dispersed (e.g. suspended or dissolved), e.g. the components may be selected from a resin, a colorant, basic dispersant, charge directors and other additives. Liquid carriers can include a mixture of a variety of different agents, such as surfactants, co-solvents, viscosity modifiers, and/or other possible ingredients.

As used herein, “electrostatic ink composition” generally refers to an ink composition, which may be in liquid form, generally suitable for use in an electrostatic printing process, sometimes termed an electrophotographic printing process. The electrostatic ink composition may include chargeable particles of resin dispersed in a liquid carrier, which may be as described herein. A colorant may be present, e.g. if the ink is to be opaque or substantial opaque or a colorant may not be present. An electrostatic ink (in printed form) or an electrostatic ink composition (for forming a printed ink in an electrostatic printing process) may comprise a charge director and/or charge adjuvant, which may be as described herein.

As used herein, “co-polymer” refers to a polymer that is polymerized from at least two monomers.

As used herein, “melt flow rate” generally refers to the extrusion rate of a resin through an orifice of defined dimensions at a specified temperature and load, usually reported as temperature/load, e.g. 190° C./2.16 kg. Flow rates can be used to differentiate grades or provide a measure of degradation of a material as a result of molding. In the present disclosure, “melt flow rate” is measured per ASTM D1238-04c Standard Test Method for Melt Flow Rates of Thermoplastics by Extrusion Plastometer. If a melt flow rate of a particular polymer is specified, unless otherwise stated, it is the melt flow rate for that polymer alone, in the absence of any of the other components of the electrostatic composition.

As used herein, “acidity,” “acid number,” or “acid value” of a polymer/resin refers to the mass of potassium hydroxide (KOH) in milligrams that neutralizes one gram of the polymer/resin comprising acidic groups. The acidity of a polymer can be measured according to standard techniques, for example as described in ASTM D1386. If the acidity of a particular polymer is specified, unless otherwise stated, it is the acidity for that polymer alone, in the absence of any of the other components of the liquid toner composition.

As used herein, “melt viscosity” generally refers to the ratio of shear stress to shear rate at a given shear stress or shear rate. Testing is generally performed using a capillary rheometer. A plastic charge is heated in the rheometer barrel and is forced through a die with a plunger. The plunger is pushed either by a constant force or at constant rate depending on the equipment. Measurements are taken once the system has reached steady-state operation. One method used is measuring Brookfield viscosity @ 140° C., units are mPa-s or cPoise. In some examples, the melt viscosity can be measured using a rheometer, e.g. a commercially available AR-2000 Rheometer from Thermal Analysis Instruments, using the geometry of: 25 mm steel plate-standard steel parallel plate, and finding the plate over plate rheometry isotherm at 120° C., 0.01 Hz shear rate. If the melt viscosity of a particular polymer is specified, unless otherwise stated, it is the melt viscosity for that polymer alone, in the absence of any of the other components of the electrostatic composition.

A certain monomer may be described herein as constituting a certain weight percentage of a polymer. This indicates that the repeating units formed from the said monomer in the polymer constitute said weight percentage of the polymer.

If a standard test is mentioned herein, unless otherwise stated, the version of the test to be referred to is the most recent at the time of filing this patent application.

As used herein, “electrostatic(ally) printing” or “electrophotographic(ally) printing” generally refers to the process that provides an image that is transferred from a photo imaging substrate or plate either directly or indirectly via an intermediate transfer member to a print substrate, e.g. a paper substrate or, in the context of the present application, an electrode. As such, the image is not substantially absorbed into the photo imaging substrate or plate on which it is applied. Additionally, “electrophotographic printers” or“electrostatic printers” generally refer to those printers capable of performing electrophotographic printing or electrostatic printing, as described above. “Liquid electrophotographic printing” is a specific type of electrophotographic printing where a liquid ink is employed in the electrophotographic process rather than a powder toner. An electrostatic printing process may involve subjecting the electrophotographic ink composition to an electric field, e.g. an electric field having a field strength of 1000 V/cm or more, in some examples 1000 V/mm or more.

A light-emitting electrochemical cell as defined herein is a cell comprising two electrodes and a layer comprising electroluminescent material between the two electrodes, such that, when an voltage, which may be an AC voltage, is applied across the electrodes by an electrical power source, e.g. an AC power source, the electroluminescent material emits light; although the electrochemical cell, for the purposes of definition, need not necessarily include the power source, e.g. the AC power source.

As used herein, the term “about” is used to provide flexibility to a numerical range endpoint by providing that a given value may be a little above or a little below the endpoint. The degree of flexibility of this term can be dictated by the particular variable.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not just the numerical values explicitly recited as the end points of the range, but also to include all the individual numerical values or sub-ranges encompassed within that range as if each numerical value and sub-range is explicitly recited. As an illustration, a numerical range of “about 1 wt % to about 5 wt %” should be interpreted to include not just the explicitly recited values of about 1 wt % to about 5 wt %, but also include individual values and subranges within the indicated range. Thus, included in this numerical range are individual values such as 2, 3.5, and 4 and sub-ranges such as from 1-3, from 2-4, and from 3-5, etc. This same principle applies to ranges reciting a single numerical value. Furthermore, such an interpretation should apply regardless of the breadth of the range or the characteristics being described.

As used herein, unless specified otherwise, wt % values are to be taken as referring to a weight-for-weight (w/w) percentage of solids in the ink composition, and not including the weight of any carrier fluid present. As used herein, unless specified otherwise, the solids include any compound or mixture forming part of the LEP ink composition that remains on a print substrate (which may be the first and/or second electrode as described herein) after printing of the LEP ink composition, whether or not the compound or mixture is a liquid or a solid when initially combined with the other components of the LEP ink composition.

Unless otherwise stated, any feature described herein can be combined with any aspect or any other feature described herein.

The present disclosure provides, in a first aspect, a light-emitting electrochemical cell comprising:
a first electrode and a second electrode;
a light-emitting layer disposed between the first and second electrodes and comprising a printed electrostatic ink comprising a thermoplastic resin having dispersed therein an electroluminescent material.

The present disclosure provides, in a second aspect, a method of making an electrostatic ink, the method comprising:
providing a carrier fluid (i) in which is dispersed a molten or a dissolved thermoplastic polymer resin and (ii) containing particles of an electroluminescent material suspended therein;
effecting precipitation of the polymer resin from the carrier fluid onto the electroluminescent material to form particles comprising the electroluminescent material with a coating comprising the thermoplastic resin in solid form thereon.

The present disclosure provides, in a third aspect, a method of making an electrostatic ink, the method comprising an electrostatic ink comprising:
chargeable particles comprising an electroluminescent material having a coating of a thermoplastic resin thereon.

The present disclosure provides, in a fourth aspect, a method of making a light-emitting electrochemical cell, the method comprising:
electrophotographically printing, using an electrostatic ink comprising chargeable particles comprising an electroluminescent material having a coating of a thermoplastic resin thereon, a light-emitting layer on a first electrode or a second electrode, or a dielectric insulating layer, which may be disposed on the first or second electrode, and then on an opposing side from the first or second electrode, disposing the other of the first and second electrodes, to form a light-emitting electrochemical cell comprising
   the first electrode and the second electrode;
   the light-emitting layer disposed between the first and second electrodes and comprising a printed electrostatic ink comprising the thermoplastic resin having dispersed therein an electroluminescent material,
   optionally wherein a dielectric insulating layer is disposed between the light-emitting layer, and the first or the second electrode. In some examples, the first and/or second electrodes may be printed, e.g. in an electrophotographic printing process using an electrostatic ink, which may be a liquid electrostatic ink, comprising a thermoplastic resin and electrically conductive particles. In some examples, if present, the dielectric insulating layer may be printed on the first or second electrode or both the first and second electrodes,
and comprising a printed electrostatic ink comprising a thermoplastic resin having dispersed therein an electroluminescent material e.g. in an electrophotographical printing process using an electrostatic ink, which may be a liquid electrostatic ink, which may or may not comprise pigmented particles (without pigment particles, it may be a clear or transparent layer, and may be disposed on a transparent electrode); with pigment particles, e.g. white particles, it may be an opaque layer, and, in some examples, disposed on an opaque electrode. The process may involve printing, e.g. electrophotographically printing, an image layer, e.g. using an electrostatic ink comprising a thermoplastic resin and a pigment selected from magenta, cyan, yellow and black, on one or more of the other layers; the image layer may lay behind or in front of the light-emitting layer (in front of the light-emitting layer' indicating that, when a viewer is looking through the layers at light being emitted from the light-emitting layer, the image layer is disposed closer to the viewer than the light-emitting layer, and ‘behind the light-emitting layer’, indicating that, when a viewer is looking through the layers at light being emitted from the light-emitting layer, the image layer is disposed further away from the viewer than the light-emitting layer.

The present disclosure describes the aspects outlined above. The present disclosure allows a light-emitting electrochemical cell to be produced using a digital printing process. The light-emitting layer, and, in some examples, the first and second electrodes and, if present, the dielectric layer, to be printed digitally, in particular using an electrophotographic printing process. This allows the layers to be selectively printed in any particular design (e.g. in the form of a picture, letters, numbers, symbols and/or patterns) and to be very thin (i.e. each layer can have the typical thickness of a printed layer, e.g. between 1 and 20 separations thickness). They can all be printed in the same printing process using the same printing equipment, e.g. using an electrophotographic, e.g. liquid electrophotographic, printing press (printer). It allows a very thin printed substrate to light up simply by applying an AC voltage across the first and second electrodes. The resultant cell is typically very durable, can be flexible and of high strength. It allows electroluminescent printed images to be used in a very wide range of applications, such as in or on electronic equipment, toys and games, for advertisement, e.g. safety and animated signs, lighting for interior and exterior decorative purposes, for personalizing image and text prints, and for customization of clothes and accessories. The luminescent printed images, which may include writing, allow for an effective way to personalize stories or add a lighted signature to a personal gift. For example, a wedding invitation may be produced with luminescent writing, e.g. in the names of the people on the invitation, or a wine company could print red-fluorescing labels for the red wines and white-fluorescing for their white wine bottles. The cell can be flat or curved. The technology is therefore very versatile and allows mass production of electroluminescent printed devices at reasonable cost. The light-emitting electrochemical cell can be flexible and high strength and can be applied to a flat or curved surface, and, in some examples, is almost unbreakable.

Herein is disclosed a light-emitting electrochemical cell comprising:
a first electrode and a second electrode;
a light-emitting layer disposed between the first and second electrodes and comprising a printed electrostatic ink comprising a thermoplastic resin having dispersed therein an electroluminescent material.

In some examples, the electroluminescent material is selected from an inorganic electroluminescent material and organic electroluminescent material.

In some examples, the inorganic electroluminescent material is selected from a doped zinc sulfide, a doped cadmium sulfide, a semi-conductor comprising a Group III element and a Group V element (e.g. selected from indium phosphide, gallium arsenide and gallium nitride), a doped diamond and an organic semiconductor (e.g. [Ru(bpy)3]2+(PF6-)2, where bpy is 2,2′-bipyridine). The doped zinc sulfide or doped cadmium sulfide may include a dopant, sometimes termed an activator, selected from copper, manganese, gold and silver. The doped zinc sulfide may further comprise a co-activator, e.g. a halide ion (e.g. selected from F, Cl, Br and I) and/or a trivalent ion (e.g. selected from Al, Ga and In). At least some of the particles of electroluminescent material, in the ink before or after printing or in the method or making the ink at any point, e.g. at the start and the end of the method, may have a size, e.g. as determined from their largest dimension when viewed using scanning electron micrograph, of 1 to 50 microns, in some examples 5 to 40 microns, in some examples 5 to 35 microns, in some examples 5 to 25 microns, in some examples 10 to 35 microns, in some examples 10 to 40 microns, in some examples 20 to 30 microns, or in some examples 5 to 25 microns. The electroluminescent material (e.g. in the ink before or after printing, and at the start or end of making the ink, e.g. before or after any grinding the occurs) may comprise particles having a D50 of 1 to 50 microns, in some examples 5 to 40 microns, in some examples 5 to 30 microns, in some examples 10 to 40 microns, in some examples 10 to 35 microns, in some examples 20 to 30 microns, or in some examples 5 to 25 microns. D50 may be measured using, for example, any standard technique for particle size distribution, e.g. using wet classification, cyclone classification laser diffraction or sieving. D50 may be measured using laser diffraction with the particles in suspension, e.g. using a standard laser diffraction particle size analyser; the D50 may be the particle size at which the cumulative volume fraction of particles reaches 50%, e.g. as described in ISO 13320:2020.

In some examples, the organic electroluminescent material comprises a π-conjugated polymer, e.g. a π-conjugated polymer selected from polyfluorenes (e.g. poly(fluorene) itself), poly(1,4-phenylene), polyphenylene vinylenes, polyphenylene ethynylenes, poly(para-phenylene sulfide), polyvinyl carbazole, polythiophenes, polyphenylenes (e.g. poly(para-phenylenevinylene), polyanthracenes, polybenzothiadiazole, polybiothiophene and polyspiro compounds. A salt may be present with the organic electroluminescent material, e.g. the π-conjugated polymer. The salt may be an inorganic or an organic salt. The organic salt may be selected from phosphonium salts, ammonium salts, pyridinium salts, imidazolium salts, and pyrrolidinium salts. The inorganic salts may comprise a cation and an anion, e.g. a cation selected from lithium cation, cesium cation, calcium cation, barium cation, rubidium cation, magnesium cation, sodium cation, potassium cation, imidazolium, pyridium, pyrrolidinium, pyrazolium, pyrazole, phosphonium, ammonium, guanidinium, uranium, thiouronium, sulfonium; and/or an anion selected from alkylsulfate, tosylate, methanesulfonate, trifluoromethanesulfonate, bis(trifluoromethylsulfonyl)imide, hexafluorophosphate, tetrafluoroborate, organoborate, thiocyanate, dicyanamide, and halides.

In some examples, the thermoplastic resin in the light-emitting layer comprises a polymer having acidic side groups, which may be a resin comprising a co-polymer of copolymers of ethylene and an ethylenically unsaturated acid of either methacrylic acid or acrylic acid.

In some examples, a dielectric insulating layer, or dielectric layer, is disposed between the light-emitting layer, and the first or the second electrode. The dielectric layer may comprise any dielectric material. The dielectric material may be selected from a polymeric material, a ceramic material and a glass. In some examples, the dielectric layer comprises anelectrostatic ink (which may arbitrarily be termed a second printed electrostatic ink) comprising a thermoplastic resin (with the electrostatic ink in the light-emitting layer being denoted a first printed electrostatic ink). The thermoplastic resin for the second printed electrostatic ink may be the same as or different from the thermoplastic resin for the first printed electrostatic ink. The dielectric layer may be opaque or transparent. For example, if the dielectric layer is disposed on the same side of the light-emitting layer as a transparent electrode, the electric layer may also be transparent, to allow light transmission through the transparent electrode and the dielectric layer. For example, if the dielectric layer is disposed on the opposite side of the light-emitting layer as a transparent electrode, the dielectric layer may also be opaque, or at least less transparent than the transparent electrode, to allow light transmission through the transparent electrode and the dielectric layer.

In some examples, the second electrode is a transparent electrode, the dielectric insulating layer is disposed between the light-emitting layer, and the first electrode. In some examples, the second printed electrostatic ink comprising a thermoplastic resin comprises a white pigment, and the first electrode may be an opaque electrode.

In some examples, the second electrode is a transparent electrode, the dielectric insulating layer is disposed between the light-emitting layer, and the second electrode; and in some examples, the second printed electrostatic ink comprises a thermoplastic resin and lacks or substantially lacks a pigment (e.g. comprising less than 5 wt %, in some examples less than 2 wt % pigment, in some examples less than 1 wt % pigment), such that it allows light transmission, and the first electrode may be an opaque electrode.

The first and/or second electrode may be a transparent electrode. A transparent electrode may comprise a transparent electrically conducting material, e.g. a material selected from an indium-doped tin oxide (ITO), a fluorine-doped tin oxide (FTO), a polymer having transparency such as an impurity-added poly(3,4-ethylenedioxythiophene) (PEDOT), and electrodes made of a carbon-based material such as a carbon nanotube or graphene.

The first and/or second electrode may be an opaque electrode. The opaque electrode may comprise an electrically conducting metal or carbon. The electrically conducting metal may be in elemental or alloyed form and may comprise a metal selected from aluminum (Al), silver (Ag), gold (Au), platinum (Pt), tin (Sn), bismuth (Bi), copper (Cu), chromium (Cr), zinc (Zn), and magnesium (Mg).

In some examples, one of the first and/or second electrode is an opaque electrode and the other of the first and/or second electrode is a transparent electrode. “Transparent” indicates that at least some light from the electroluminescence is transmitted through the material; “opaque” indicates that less light is transmitted than for a transparent electrode, e.g. an electrode comprising indium tin oxide, and may not allow any light from the electroluminescence to be transmitted.

In some examples, the first and/or second electrode, which may be an opaque electrode, may comprise a layer formed in an electrophotographic printing process, e.g. a liquid electrophotographic printing process, e.g. using an electrostatic ink, which may be a liquid electrostatic ink, comprising a thermoplastic resin and an electrically conductive pigment. The electrostatic ink in the first and/or second electrode may arbitrarily be termed a third electrostatic ink herein. The electrically conductive pigment may comprise a material selected from a metal, carbon and a conductive polymer. The conductive pigment may comprises a metal selected from aluminium, tin, a transition metal, and alloys of any one of more thereof. The conductive polymer may be selected from the conductive polymer is selected from a poly(fluorene), a polyphenylene, a polypyrene, a polyazulene, a polynaphthalene, a poly(acetylene), a poly(p-phenylene vinylene), a poly(pyrrole), a polycarbazole, a polyindole, a polyazepines, a polyaniline, a poly(thiophene), a poly(3,4-ethylenedioxythiophene), a poly(p-phenylene sulfide), a polythienylenevinylene and a poly-1,6-heptadiyne. The conductive pigment may be in the form of flakes. The conductive species may be an elongate conductive species, e.g. an elongate conductive species selected from carbon nanotubes, graphene and metals. The electrically conductive species may comprise electrically conductive metal particles comprising: a core comprising a first metal, and a shell comprising a second metal, wherein the shell encloses the core at least partially, and wherein the first metal and the second metal are not the same. In some examples, the first metal and the second metal are selected from the group consisting of copper, silver, gold, platinum, titanium, chromium, manganese, iron, nickel rhodium, iridium, and combinations thereof. In some examples, the first metal is copper and the second metal is silver.

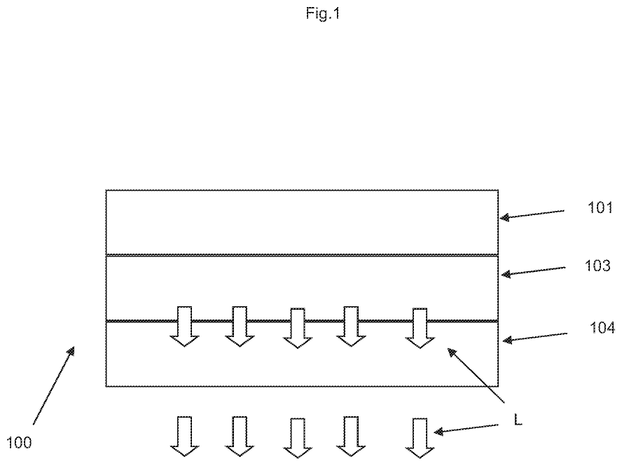

FIG. 1 shows an example of a light-emitting electrochemical cell comprising a first electrode 101 and a second electrode 104 and a light-emitting layer 103 disposed between the first and second electrodes. In this example, the first electrode is an opaque electrode and the second electrode is a transparent electrode. The light-emitting layer 103 comprises a printed electrostatic ink comprising a thermoplastic resin having dispersed therein an electroluminescent material. The first and/or second electrodes may comprise a printed electrostatic ink (to be termed, arbitrarily, a third electrostatic ink) comprising a thermoplastic resin and an electrically conductive pigment. Light emitted from the light-emitting layer 103 is shown with arrows pointing down the page, denoted with an ‘L’.

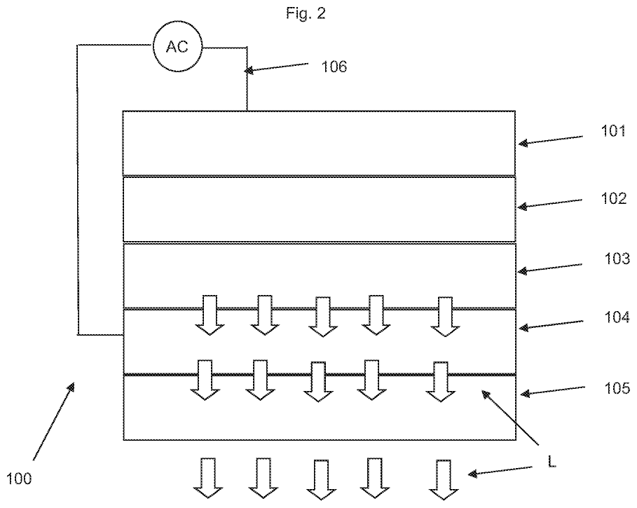

FIG. 2 shows an example of a light-emitting electrochemical cell comprising a first electrode 101 and a second electrode 104 and a light-emitting layer 103 disposed between the first and second electrodes. The layers are denoted in the figure as they are in FIG. 1 and may be as described above. In this embodiment, a dielectric insulating layer 102 is disposed between the light-emitting layer, and the first electrode. The dielectric layer may comprise a second printed electrostatic ink comprising a thermoplastic resin, and a white pigment. The second electrode is disposed upon a transparent substrate 105, which may be glass or a clear plastic, for example—this acts as a support for the second electrode. The first and/or second electrodes may comprise a third printed electrostatic ink comprising a thermoplastic resin and an electrically conductive pigment.

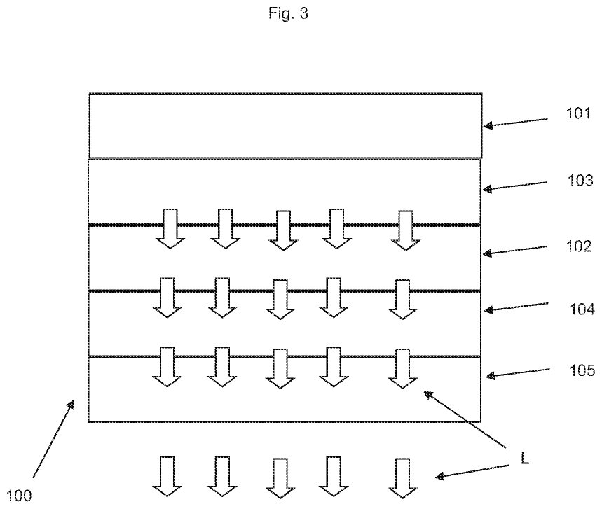

FIG. 3 shows an example of a light-emitting electrochemical cell comprising a first electrode 101 and a second electrode 104 and a light-emitting layer 103 disposed between the first and second electrodes. The layers are denoted in the figure as they are in FIGS. 1 and 2 and may be as described above. In this embodiment, a dielectric insulating layer 102 is disposed between the light-emitting layer, and the second electrode (instead of between the light-emitting layer and the first electrode as in FIG. 1). The dielectric layer may comprise a second printed electrostatic ink comprising a thermoplastic resin, and may be a transparent layer (e.g. the electrostatic ink comprising a very low amount of pigment or no pigment, to allow light transmission through the ink). The first and/or second electrodes may comprise a third printed electrostatic ink comprising a thermoplastic resin and an electrically conductive pigment.

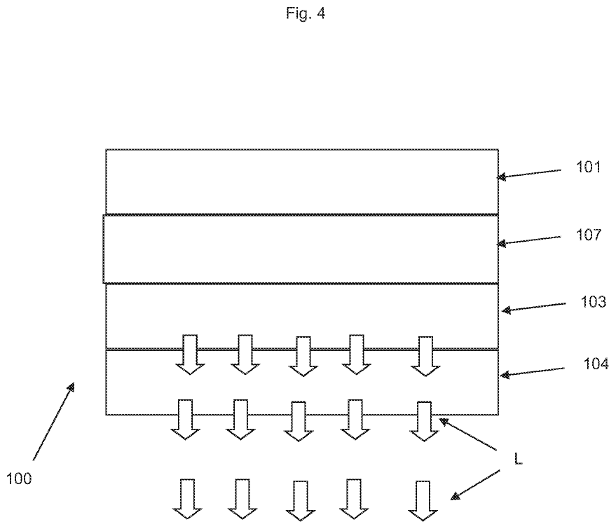

FIG. 4 shows an example of a light-emitting electrochemical cell similar to that shown in FIG. 1, i.e. comprising the first electrode 101 and the second electrode 104, which is a transparent electrode, and the light-emitting layer 103 disposed between the first and second electrodes. In this example, however, an image layer 107 is disposed between the first electrode 101 and the light-emitting layer 103. In an example, the image layer 107 may be a printed layer comprising one or more pigments selected from magenta, cyan, yellow and black—the image layer may be printed in an electrophotographic printing process using electrostatic ink, e.g. it may be a printed electrostatic ink, which may be arbitrarily termed a fourth printed ink, comprising a thermoplastic resin and a pigment selected from magenta, cyan, yellow and black, and combinations thereof. Light emitted from the light-emitting layer 103 is shown with arrows pointing down the page, denoted with an ‘L’.

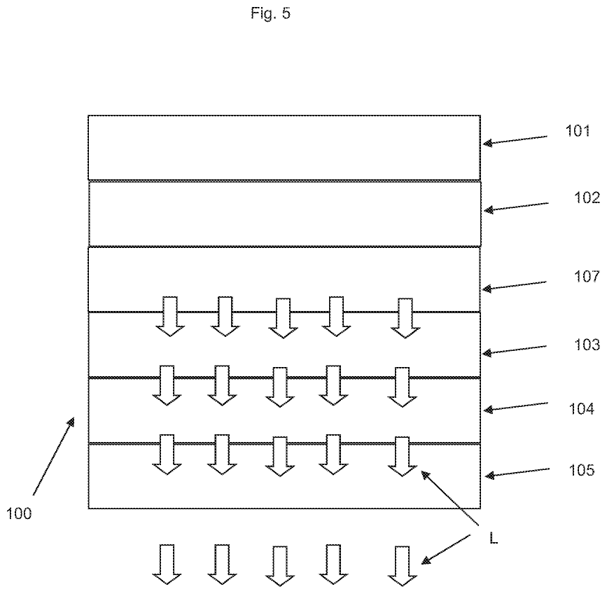

FIG. 5 shows an example of a light-emitting electrochemical cell, similar to that of FIG. 2, i.e. comprising the first electrode 101 and the second electrode 104, which is a transparent electrode, and a light-emitting layer 103 disposed between the first and second electrodes. In this embodiment, a dielectric insulating layer 102 is disposed between the light-emitting layer, and the first electrode 101. The second electrode 104 is disposed upon a transparent substrate 105. In this example, however, an image layer 107 is disposed between the dielectric insulating layer 102 and the light-emitting layer 103. In an example, the image layer 107 may be a printed layer comprising one or more pigments selected from magenta, cyan, yellow and black. In an example, the image layer 107 may be a printed layer comprising one or more pigments selected from magenta, cyan, yellow and black—the image layer may be printed in an electrophotographic printing process using electrostatic ink, e.g. it may be a printed electrostatic ink, which may be arbitrarily termed a fourth printed ink, comprising a thermoplastic resin and a pigment selected from magenta, cyan, yellow and black, and combinations thereof. Light emitted from the light-emitting layer 103 is shown with arrows pointing down the page, denoted with an ‘L’.

In the examples herein, the layers may be deposited sequentially, e.g. starting with one of the outermost layers (e.g. the second electrode 104 or first electrode 101 in FIG. 1 or 4; or the transparent substrate 105 or first electrode 101 in FIGS. 2, 3 and 5 (or a further substrate (not shown) on which the first electrode 101 could be deposited) and depositing the other layers sequentially on them, e.g. in an electrophotographic printing process as described herein.

### Method of Making an Electrostatic Ink

Herein is also disclosed a method of making an electrostatic ink composition, the method comprising:
providing a carrier fluid (i) in which is dispersed a molten or dissolved thermoplastic polymer resin and (ii) containing particles of an electroluminescent material suspended therein;
effecting precipitation of the polymer resin from the carrier fluid onto the electroluminescent material to form particles comprising the electroluminescent material with a coating comprising the thermoplastic resin in solid form thereon.

In some examples, the method of producing the electrostatic ink composition involves heating a dispersion of a polymer resin in a carrier fluid to dissolve the polymer resin. In some examples, the polymer resin is insoluble in the carrier fluid (which may be the carrier liquid as described herein) at room temperature (e.g. 20-25° C.) but soluble in the carrier fluid at elevated temperatures, for example at a temperature of at least 50° C., for example at a temperature of at least 60° C., for example at a temperature of at least 70° C., for example at a temperature of at least 80° C., for example at a temperature of at least 90° C., for example at a temperature of at least 100° C., for example at a temperature of at least 110° C., for example at a temperature of at least 120° C. The dispersion of the polymer resin in the carrier fluid may be heated to any of the above stated temperatures for sufficient time until the polymer resin has dissolved. Dissolution may be confirmed by the carrier fluid appearing clear and homogenous. In some examples, the dispersion of polymer resin in the carrier fluid may be mixed at a rate of less than 500 rpm, for example less than 400 rpm, for example less than 300 rpm, for example less than 200 rpm until dissolution is complete. In some examples, heating a dispersion of polymer resin in carrier fluid causes the polymer resin to swell with carrier fluid. In some examples, the dispersion of polymer resin in carrier fluid is heated to swell the polymer resin. Swelling of the polymer resin allows better encapsulation of the pigment particle.

In some examples, the electroluminescent material, e.g. in the form of particles, may be suspended in the carrier fluid before any cooling occurs, for example at the temperature at which dissolution of the polymer resin in the carrier fluid was carried out. In some examples, the carrier fluid may be cooled to an intermediate temperature before the electroluminescent material is suspended in the carrier fluid. The intermediate temperature may be any temperature above the cloud point of the solution comprising the carrier fluid and the dissolved polymer resin. The cloud point of any given carrier fluid-polymer resin system can be readily determined by heating and slowly cooling the solution and is the temperature at which dissolved solids begin to precipitate, giving a phase separation and a cloudy or turbid appearance. In some examples, the solution comprising the carrier fluid and the dissolved polymer resin is cooled to at least 2° C., for example at least 3° C., for example at least 4° C., for example at least 5° C., for example at least 6° C., for example at least 7° C., for example at least 8° C., for example at least 9° C., for example at least 10° C. above the cloud point before the electroluminescent material is suspended in the carrier fluid.

In some examples, the electroluminescent material is mixed into the solution of the polymer resin dissolved in the carrier fluid at a shear rate of 12 000 rpm or less, for example 11 000 rpm or less, for example 10 000 rpm or less, for example 9000 rpm or less to ensure complete dispersion before the precipitation of the polymer resin is effected. In some examples, the electroluminescent material is mixed into the solution of the polymer resin dissolved in the carrier fluid at a shear rate of 1000 rpm to 12 000 rpm, in some examples 3000 rpm to 8000 rpm, in some examples 3000 rpm to 6000 rpm, in some examples 5000 rpm to 8000 rpm, in some examples about 7000 rpm. In other examples, the electroluminescent material is mixed into the solution of the polymer resin dissolved in the carrier fluid at a shear rate of 100 rpm or less, for example 90 rpm or less, for example 80 rpm or less, for example 70 rpm or less, for example 60 rpm or less, for example 50 rpm or less to ensure complete dispersion before the precipitation of the polymer resin is effected. In some examples, following dispersion of the electroluminescent material at a low shear rate, the rate of mixing may be increased to less than 100 rpm, for example less than 90 rpm, for example less than 80 rpm, for example 70 rpm or less. In some examples, following dispersion of the electroluminescent material, the rate of mixing may be lowered to less than 500 rpm, for example less than 400 rpm, for example less than 300 rpm, for example less than 200 rpm, for example 100 rpm or less, for example less than 90 rpm, for example less than 80 rpm, for example less than 70 rpm, for example less than 60 rpm, for example 50 rpm or less while precipitation (which may be the first of two or more precipitation stages) is effected.

In some examples, once the electroluminescent material is fully dispersed, the system is cooled at a controlled or an uncontrolled rate until precipitation of the resin from solution (and onto the particles of the electroluminescent material). For example, the system is cooled at a controlled or an uncontrolled rate through the cloud point of the solution to effect precipitation of the polymer resin from solution.

In some examples, once the solution has cooled to the point that it is biphasic, below the cloud point temperature and the polymer resin has precipitated, the system is then reheated to above the cloud point of the solution, for example to at least 5° C. above the cloud point of the solution, for example at least 10° C. above the cloud point of the solution, at least 15° C. above the cloud point temperature of the solution, at least 20° C. above the cloud point temperature of the solution. The reheating of the solution to above the cloud point followed by a second precipitation is thought to improve the final encapsulation of the electroluminescent material particles by the polymer resin.

The second precipitation is effected by controlling the cooling of the system such that solubility of the resin in the carrier fluid is reduced and precipitation of the resin occurs. In some examples, the temperature of the carrier fluid is lowered through a controlled cooling process at a given rate. For example, after addition of the electroluminescent material particles, the temperature of the carrier fluid may be lowered at a rate of less than 7° C. per hour, for example less than 6° C. per hour, for example less than 5° C. per hour, for example less than 4° C. per hour, for example 3° C. per hour.

In some examples, the second precipitation is effected through controlled cooling through the cloud point of the polymer resin-carrier fluid system. For example, the controlled cooling at a rate of less than 7° C./hour, for example a rate of 3° C./hour, may be carried out beginning at a temperature of 5° C. above the cloud point of the solution and continued until a temperature of at least 5° C. below the cloud point of the solution. In some examples, once the temperature has been lowered in a controlled manner to at least 5° C. below the cloud point of the solution, the system is then cooled at an uncontrolled rate to room temperature.

In some examples, the electroluminescent particles suspended in the carrier fluid have a particle size, D50, as described above, e.g. of from 10 to 40 microns, and the method does not substantially reduce the particle size of the electroluminescent particles. In some examples, following the precipitation of the resin from the carrier fluid, the composition comprising polymer resin-coated electroluminescent material particles in carrier fluid may be subjected to a grinding treatment. The method may involves, after effecting the precipitation, grinding, e.g. in a ball mill, the particles comprising the electroluminescent material with the coating thereon; the grinding may be carried out at a rotation rate of 500 rpm, e.g. 200 rpm or less and/or for 5 hours or less, e.g. 2 hours or less, and wherein a charge adjuvant and/or a charge director is present with the particles during the grinding. In some examples, the method may involve, after effecting the precipitation, grinding in a ball mill the particles comprising the electroluminescent material with the coating thereon, the grinding being carried out at a rotation rate of 200 rpm or less, e.g. from 50 rpm to 200 rpm, and/or for 2 hours or less, e.g. from 30 minutes to 2 hours, e.g. 30 minutes to 90 minutes, and wherein a charge adjuvant and/or a charge director is present with the particles during the grinding. Grinding at this rate and for this period of time has been found not to substantially reduce the particle size or adversely effect the electroluminescent properties of the electroluminescent material.

The grinding treatment may comprise grinding the composition at a temperature of less than 100° C., for example less than 90° C., for example less than 80° C., for example less than 70° C., for example less than 60° C., for example less than 50° C., for example 40° C. or less. The grinding treatment may comprise grinding the composition at a speed of less than 500 rpm, for example less than 400 rpm, for example less than 300 rpm, for example 250 rpm or less. The grinding treatment may comprise grinding the composition at a NVS content of less than 40%, for example less than 30%, for example less than 20%, for example 18% or less. The grinding treatment may comprise grinding the composition for less than 12 hours, for example less than 6 hours, for example less than 5 hours, for example less than 4 hours, for example less than 3 hours, for example 2 hours or less, e.g. from 30 minutes to 2 hours. The grinding treatment may be carried out in the presence of a charge adjuvant and/or charge director, as described herein (i.e. a charge adjuvant and/or charge director may be added only at the grinding stage, and not before in the precipitation stage) comprise grinding the composition until sufficient charge develops on the resin particles for them to be used in an electrostatic printing process.

The grinding may be carried out on any commercial attritor, for example an S0, SD-1 or S1 attritor from Union Process. The grinding may be carried out using a metallic grinding media, or a non-metallic grinding media. The grinding media may be or comprise carbon steel, or chrome steel, or stainless steel, or steel shot. The grinding media may be or comprise alumina or other ceramic material such as glass mullite silicon carbide silicon nitride, tungsten carbide zirconium oxide, or zirconium silicate. The grinding media may be or comprise spherical or substantially spherical media, satellites or radius-end cylinders. Satellites will be understood as being substantially spherical with a protruding band around the circumference. The grinding media may be 35 mm or less in diameter, 31 mm or less in diameter, 30 mm or less in diameter, for example 26 mm or less, 25 mm or less, 15 mm or less, 12.7 mm or less in diameter, 10 mm or less, for example 9.5 mm or less, 7.9 mm or less, 5.6 mm or less, 6.4 mm or less, 3.9 mm or less, 3.2 mm or less, 2.4 mm or less, 2mm or less, for example 1.7 mm or less, 1.4 mm or less, 1 mm or less, 1.18 mm or less, 0.7 mm or less, 0.6 mm or less, 0.5 mm or less, 0.4 mm or less, or 0.25 mm or less in diameter.

The thermoplastic resin, the charge adjuvant and the charge director may be as described below.

Herein is also disclosed an electrostatic ink comprising:
chargeable particles comprising an electroluminescent material having a coating of a thermoplastic resin thereon.

The electrostatic ink may be formable according to the method of the second aspect described herein. The electrostatic ink may be a liquid electrostatic ink comprising a liquid carrier having dispersed therein the chargeable particles comprising an electroluminescent material having a coating of a thermoplastic resin thereon. The electroluminescent material, the thermoplastic resin and the liquid carrier may be as described herein. For example, the electroluminescent material may be selected from an inorganic electroluminescent material selected from a doped zinc sulfide, a semi-conductor comprising a Group Ill element and a Group V element, e.g. selected from indium phosphide, gallium arsenide and gallium nitride, a doped diamond and an organic semiconductor. Similarly, the thermoplastic resin may comprises a co-polymer of ethylene and an ethylenically unsaturated acid of either methacrylic acid or acrylic acid and/or (ii) the ink is a liquid electrostatic ink, and chargeable particles are suspended in a liquid carrier and the ink further comprises a charge director and/or a charge adjuvant.

### Thermoplastic Resin

Each of the electrostatic ink compositions described herein (e.g. for forming the first, second, third electrostatic and/or fourth inks in printed form) includes chargeable particles comprising a thermoplastic resin. A thermoplastic polymer is sometimes referred to as a thermoplastic resin. The resin may coat any pigment present in the electrostatic ink compositions, which (for the first electrostatic ink for the light-emitting layer) may be an electroluminescent material, or (for the second electrostatic ink for the dielectric layer or the fourth electrostatic ink for an image layer) may be a non-electrically conductive pigment, e.g. a pigment selected from a white, black, a cyan, a yellow and a magenta pigment), or (for the third electrostatic ink for the first and/or second electrode) an electrically conductive pigment, such that the particles include a core of conductive pigment, and have an outer layer of resin thereon. The outer layer of resin may coat the conductive pigment partially or completely. The second electrostatic ink may lack a pigment (e.g. if forming a transparent di-electric layer).

The resin for any of the first, second, third and fourth electrostatic inks may be as described below. The resin typically includes a polymer, typically a thermoplastic polymer. In some examples, the polymer of the resin may be selected from ethylene acrylic acid copolymers; ethylene methacrylic acid copolymers; ethylene vinyl acetate copolymers; copolymers of ethylene (e.g. 80 wt % to 99.9 wt %), and alkyl (e.g. C1 to C5) ester of methacrylic or acrylic acid (e.g. 0.1 wt % to 20 wt %); copolymers of ethylene (e.g. 80 wt % to 99.9 wt %), acrylic or methacrylic acid (e.g. 0.1 wt % to 20.0 wt %) and alkyl (e.g. C1 to C5) ester of methacrylic or acrylic acid (e.g. 0.1 wt % to 20 wt %); polyethylene; polystyrene; isotactic polypropylene (crystalline); ethylene ethyl acrylate; polyesters; polyvinyl toluene; polyamides; styrene/butadiene copolymers; epoxy resins; acrylic resins (e.g. copolymer of acrylic or methacrylic acid and at least one alkyl ester of acrylic or methacrylic acid wherein alkyl is, in some examples, from 1 to about 20 carbon atoms, such as methyl methacrylate (e.g. 50 wt % to 90 wt %)/methacrylic acid (e.g. 0 wt % to 20 wt %)/ethylhexylacrylate (e.g. 10 wt % to 50 wt %)); ethylene-acrylate terpolymers: ethylene-acrylic esters-maleic anhydride (MAH) or glycidyl methacrylate (GMA) terpolymers; ethylene-acrylic acid ionomers and combinations thereof.

The resin may comprise a polymer having acidic side groups. The polymer having acidic side groups may have an acidity of 50 mg KOH/g or more, in some examples an acidity of 60 mg KOH/g or more, in some examples an acidity of 70 mg KOH/g or more, in some examples an acidity of 80 mg KOH/g or more, in some examples an acidity of 90 mg KOH/g or more, in some examples an acidity of 100 mg KOH/g or more, in some examples an acidity of 105 mg KOH/g or more, in some examples 110 mg KOH/g or more, in some examples 115 mg KOH/g or more. The polymer having acidic side groups may have an acidity of 200 mg KOH/g or less, in some examples 190 mg or less, in some examples 180 mg or less, in some examples 130 mg KOH/g or less, in some examples 120 mg KOH/g or less. Acidity of a polymer, as measured in mg KOH/g can be measured using standard procedures known in the art, for example using the procedure described in ASTM D1386.

The resin may comprise a polymer, in some examples a polymer having acidic side groups, that has a melt flow rate of less than about 60 g/10 minutes, in some examples about 50 g/10 minutes or less, in some examples about 40 g/10 minutes or less, in some examples 30 g/10 minutes or less, in some examples 20 g/10 minutes or less, in some examples 10 g/10 minutes or less. In some examples, all polymers having acidic side groups and/or ester groups in the particles each individually have a melt flow rate of less than 90 g/10 minutes, 80 g/10 minutes or less, in some examples 80 g/10 minutes or less, in some examples 70 g/10 minutes or less, in some examples 70 g/10 minutes or less, in some examples 60 g/10 minutes or less.

The polymer having acidic side groups can have a melt flow rate of about 10 g/10 minutes to about 120 g/10 minutes, in some examples about 10 g/10 minutes to about 70 g/10 minutes, in some examples about 10 g/10 minutes to 40 g/10 minutes, in some examples 20 g/10 minutes to 30 g/10 minutes. The polymer having acidic side groups can have a melt flow rate of in some examples about 50 g/10 minutes to about 120 g/10 minutes, in some examples 60 g/10 minutes to about 100 g/10 minutes. The melt flow rate can be measured using standard procedures known in the art, for example as described in ASTM D1238.

The acidic side groups may be in free acid form or may be in the form of an anion and associated with one or more counterions, typically metal counterions, e.g. a metal selected from the alkali metals, such as lithium, sodium and potassium, alkali earth metals, such as magnesium or calcium, and transition metals, such as zinc. The polymer having acidic sides groups can be selected from resins such as copolymers of ethylene and an ethylenically unsaturated acid of either acrylic acid or methacrylic acid; and ionomers thereof, such as methacrylic acid and ethylene-acrylic or methacrylic acid copolymers which are at least partially neutralized with metal ions (e.g. Zn, Na, Li) such as SURLYN® ionomers. The polymer comprising acidic side groups can be a copolymer of ethylene and an ethylenically unsaturated acid of either acrylic or methacrylic acid, where the ethylenically unsaturated acid of either acrylic or methacrylic acid constitute from 5 wt % to about 25 wt % of the copolymer, in some examples from 10 wt % to about 20 wt % of the copolymer.

The resin may comprise two different polymers having acidic side groups. The two polymers having acidic side groups may have different acidities, which may fall within the ranges mentioned above. The resin may comprise a first polymer having acidic side groups that has an acidity of from 50 mg KOH/g to 110 mg KOH/g and a second polymer having acidic side groups that has an acidity of 110 mg KOH/g to 130 mg KOH/g.

The resin may comprise two different polymers having acidic side groups: a first polymer having acidic side groups that has a melt flow rate of about 10 g/10 minutes to about 50 g/10 minutes and an acidity of from 50 mg KOH/g to 110 mg KOH/g, and a second polymer having acidic side groups that has a melt flow rate of about 50 g/10 minutes to about 120 g/10 minutes and an acidity of 110 mg KOH/g to 130 mg KOH/g. The first and second polymers may be absent of ester groups.

The resin may comprise two different polymers having acidic side groups: a first polymer that is a copolymer of ethylene (e.g. 92 to 85 wt %, in some examples about 89 wt %) and acrylic or methacrylic acid (e.g. 8 to 15 wt %, in some examples about 11 wt %) having a melt flow rate of 80 to 110 g/10 minutes and a second polymer that is a co-polymer of ethylene (e.g. about 80 to 92 wt %, in some examples about 85 wt %) and acrylic acid (e.g. about 18 to 12 wt %, in some examples about 15 wt %), having a melt viscosity lower than that of the first polymer, the second polymer for example having a melt viscosity of 15000 poise or less, in some examples a melt viscosity of 10000 poise or less, in some examples 1000 poise or less, in some examples 100 poise or less, in some examples 50 poise or less, in some examples 10 poise or less. Melt viscosity can be measured using standard techniques. The melt viscosity can be measured using a rheometer, e.g. a commercially available AR-2000 Rheometer from Thermal Analysis Instruments, using the geometry of: 25mm steel plate-standard steel parallel plate, and finding the plate over plate rheometry isotherm at 120° C., 0.01 hz shear rate.

In any of the resins mentioned above, the ratio of the first polymer having acidic side groups to the second polymer having acidic side groups can be from about 10:1 to about 2:1. In another example, the ratio can be from about 6:1 to about 3:1, in some examples about 4:1.

The resin may comprise a polymer having a melt viscosity of 15000 poise or less, in some examples a melt viscosity of 10000 poise or less, in some examples 1000 poise or less, in some examples 100 poise or less, in some examples 50 poise or less, in some examples 10 poise or less; said polymer may be a polymer having acidic side groups as described herein. The resin may comprise a first polymer having a melt viscosity of 15000 poise or more, in some examples 20000 poise or more, in some examples 50000 poise or more, in some examples 70000 poise or more; and in some examples, the resin may comprise a second polymer having a melt viscosity less than the first polymer, in some examples a melt viscosity of 15000 poise or less, in some examples a melt viscosity of 10000 poise or less, in some examples 1000 poise or less, in some examples 100 poise or less, in some examples 50 poise or less, in some examples 10 poise or less. The resin may comprise a first polymer having a melt viscosity of more than 60000 poise, in some examples from 60000 poise to 100000 poise, in some examples from 65000 poise to 85000 poise; a second polymer having a melt viscosity of from 15000 poise to 40000 poise, in some examples 20000 poise to 30000 poise, and a third polymer having a melt viscosity of 15000 poise or less, in some examples a melt viscosity of 10000 poise or less, in some examples 1000 poise or less, in some examples 100 poise or less, in some examples 50 poise or less, in some examples 10 poise or less; an example of the first polymer is Nucrel 960 (from DuPont), and example of the second polymer is Nucrel 699 (from DuPont), and an example of the third polymer is AC-5120 (from Honeywell). The first, second and third polymers may be polymers having acidic side groups as described herein. The melt viscosity can be measured using a rheometer, e.g. a commercially available AR-2000 Rheometer from Thermal Analysis Instruments, using the geometry of: 25 mm steel plate-standard steel parallel plate, and finding the plate over plate rheometry isotherm at 120° C., 0.01 hz shear rate.

If resin comprises a single type of resin polymer, the resin polymer (excluding any other components of the electrostatic ink composition) may have a melt viscosity of 6000 poise or more, in some examples a melt viscosity of 8000 poise or more, in some examples a melt viscosity of 10000 poise or more, in some examples a melt viscosity of 12000 poise or more. If the resin comprises a plurality of polymers all the polymers of the resin may together form a mixture (excluding any other components of the electrostatic ink composition) that has a melt viscosity of 6000 poise or more, in some examples a melt viscosity of 8000 poise or more, in some examples a melt viscosity of 10000 poise or more, in some examples a melt viscosity of 12000 poise or more. Melt viscosity can be measured using standard techniques. The melt viscosity can be measured using a rheometer, e.g. a commercially available AR-2000 Rheometer from Thermal Analysis Instruments, using the geometry of: 25 mm steel plate-standard steel parallel plate, and finding the plate over plate rheometry isotherm at 120° C., 0.01 hz shear rate.

The resin may comprise two different polymers having acidic side groups that are selected from copolymers of ethylene and an ethylenically unsaturated acid of either methacrylic acid or acrylic acid; and ionomers thereof, such as methacrylic acid and ethylene-acrylic or methacrylic acid copolymers which are at least partially neutralized with metal ions (e.g. Zn, Na, Li) such as SURLYN® ionomers. The resin may comprise (i) a first polymer that is a copolymer of ethylene and an ethylenically unsaturated acid of either acrylic acid and methacrylic acid, wherein the ethylenically unsaturated acid of either acrylic or methacrylic acid constitutes from 8 wt % to about 16 wt % of the copolymer, in some examples 10 wt % to 16 wt % of the copolymer; and (ii) a second polymer that is a copolymer of ethylene and an ethylenically unsaturated acid of either acrylic acid and methacrylic acid, wherein the ethylenically unsaturated acid of either acrylic or methacrylic acid constitutes from 12 wt % to about 30 wt % of the copolymer, in some examples from 14 wt % to about 20 wt % of the copolymer, in some examples from 16 wt % to about 20 wt % of the copolymer in some examples from 17 wt % to 19 wt % of the copolymer.

In an example, the resin constitutes about 5 to 90%, in some examples about 5 to 80%, by weight of the solids of the electrostatic ink composition. In another example, the resin constitutes about 10 to 60% by weight of the solids of the electrostatic ink composition. In another example, the resin constitutes about 15 to 40% by weight of the solids of the electrostatic ink composition. In another example, the resin constitutes about 60 to 95% by weight, in some examples from 80 to 90% by weight, of the solids of the electrostatic ink composition.

The resin may comprise a polymer having acidic side groups, as described above (which may be free of ester side groups), and a polymer having ester side groups. The polymer having ester side groups is, in some examples, a thermoplastic polymer. The polymer having ester side groups may further comprise acidic side groups. The polymer having ester side groups may be a co-polymer of a monomer having ester side groups and a monomer having acidic side groups. The polymer may be a co-polymer of a monomer having ester side groups, a monomer having acidic side groups, and a monomer absent of any acidic and ester side groups. The monomer having ester side groups may be a monomer selected from esterified acrylic acid or esterified methacrylic acid. The monomer having acidic side groups may be a monomer selected from acrylic or methacrylic acid. The monomer absent of any acidic and ester side groups may be an alkylene monomer, including, but not limited to, ethylene or propylene. The esterified acrylic acid or esterified methacrylic acid may, respectively, be an alkyl ester of acrylic acid or an alkyl ester of methacrylic acid. The alkyl group in the alkyl ester of acrylic or methacrylic acid may be an alkyl group having 1 to 30 carbons, in some examples 1 to 20 carbons, in some examples 1 to 10 carbons; in some examples selected from methyl, ethyl, iso-propyl, n-propyl, t-butyl, iso-butyl, n-butyl and pentyl.

The polymer having ester side groups may be a co-polymer of a first monomer having ester side groups, a second monomer having acidic side groups and a third monomer which is an alkylene monomer absent of any acidic and ester side groups. The polymer having ester side groups may be a co-polymer of (i) a first monomer having ester side groups selected from esterified acrylic acid or esterified methacrylic acid, in some examples an alkyl ester of acrylic or methacrylic acid, (ii) a second monomer having acidic side groups selected from acrylic or methacrylic acid and (iii) a third monomer which is an alkylene monomer selected from ethylene and propylene. The first monomer may constitute 1 to 50% by weight of the co-polymer, in some examples 5 to 40% by weight, in some examples 5 to 20% by weight of the copolymer, in some examples 5 to 15% by weight of the copolymer. The second monomer may constitute 1 to 50% by weight of the co-polymer, in some examples 5 to 40% by weight of the co-polymer, in some examples 5 to 20% by weight of the co-polymer, in some examples 5 to 15% by weight of the copolymer. In an example, the first monomer constitutes 5 to 40% by weight of the co-polymer, the second monomer constitutes 5 to 40% by weight of the co-polymer, and with the third monomer constituting the remaining weight of the copolymer. In an example, the first monomer constitutes 5 to 15% by weight of the co-polymer, the second monomer constitutes 5 to 15% by weight of the co-polymer, with the third monomer constituting the remaining weight of the copolymer. In an example, the first monomer constitutes 8 to 12% by weight of the co-polymer, the second monomer constitutes 8 to 12% by weight of the co-polymer, with the third monomer constituting the remaining weight of the copolymer. In an example, the first monomer constitutes about 10% by weight of the co-polymer, the second monomer constitutes about 10% by weight of the co-polymer, and with the third monomer constituting the remaining weight of the copolymer. The polymer having ester side groups may be selected from the Bynel® class of monomer, including Bynel 2022 and Bynel 2002, which are available from DuPont®.

The polymer having ester side groups may constitute 1% or more by weight of the total amount of the resin polymers in the resin, e.g. the total amount of the polymer or polymers having acidic side groups and polymer having ester side groups. The polymer having ester side groups may constitute 5% or more by weight of the total amount of the resin polymers in the resin, in some examples 8% or more by weight of the total amount of the resin polymers in the resin, in some examples 10% or more by weight of the total amount of the resin polymers in the resin, in some examples 15% or more by weight of the total amount of the resin polymers in the resin, in some examples 20% or more by weight of the total amount of the resin polymers in the resin, in some examples 25% or more by weight of the total amount of the resin polymers in the resin, in some examples 30% or more by weight of the total amount of the resin polymers in the resin, in some examples 35% or more by weight of the total amount of the resin polymers in the resin. The polymer having ester side groups may constitute from 5% to 50% by weight of the total amount of the resin polymers in the resin, in some examples 10% to 40% by weight of the total amount of the resin polymers in the resin, in some examples 15% to 30% by weight of the total amount of the polymers in the resin.

The polymer having ester side groups may have an acidity of 50 mg KOH/g or more, in some examples an acidity of 60 mg KOH/g or more, in some examples an acidity of 70 mg KOH/g or more, in some examples an acidity of 80 mg KOH/g or more. The polymer having ester side groups may have an acidity of 100 mg KOH/g or less, in some examples 90 mg KOH/g or less. The polymer having ester side groups may have an acidity of 60 mg KOH/g to 90 mg KOH/g, in some examples 70 mg KOH/g to 80 mg KOH/g.

The polymer having ester side groups may have a melt flow rate of about 10 g/10 minutes to about 120 g/10 minutes, in some examples about 10 g/10 minutes to about 50 g/10 minutes, in some examples about 20 g/10 minutes to about 40 g/10 minutes, in some examples about 25 g/10 minutes to about 35 g/10 minutes.

In an example, the polymer or polymers of the resin can be selected from the Nucrel family of toners (e.g. Nucrel 403™, Nucrel 407™, Nucrel 609HS™, Nucrel 908HS™, Nucrel 1202HC™, Nucrel 30707™, Nucrel 1214™, Nucrel 903™, Nucrel 3990™, Nucrel 910™, Nucrel 925™, Nucrel 699™, Nucrel 599™, Nucrel 960™, Nucrel RX 76™, Nucrel 2806™, Bynell 2002, Bynell 2014, and Bynell 2020 (sold by E. I. du PONT)), the Aclyn family of toners (e.g. Aaclyn 201 , Aclyn 246, Aclyn 285, and Aclyn 295), and the Lotader family of toners (e.g. Lotader 2210, Lotader, 3430, and Lotader 8200 (sold by Arkema)).

### Charge Director

The electrostatic ink composition and/or electrostatic ink described herein (e.g. the first, second, third and/or fourth electrostatic ink) can comprise a charge director. A charge director can be added to an electrostatic ink composition to impart a charge of a desired polarity and/or maintain sufficient electrostatic charge on the resin particles of an electrostatic ink composition. The charge director may comprise ionic compounds, particularly metal salts of fatty acids, metal salts of sulfo-succinates, metal salts of oxyphosphates, metal salts of alkyl-benzenesulfonic acid, metal salts of aromatic carboxylic acids or sulfonic acids, as well as zwitterionic and non-ionic compounds, such as polyoxyethylated alkylamines, lecithin, polyvinylpyrrolidone, organic acid esters of polyvalent alcohols, etc. The charge director can be selected from, but is not limited to, oil-soluble petroleum sulfonates (e.g. neutral Calcium Petronate™, neutral Barium Petronate™, and basic Barium Petronate™), polybutylene succinimides (e.g. OLOA™ 1200 and Amoco 575), and glyceride salts (e.g. sodium salts of phosphated mono- and diglycerides with unsaturated and saturated acid substituents), sulfonic acid salts including, but not limited to, barium, sodium, calcium, and aluminum salts of sulfonic acid. The sulfonic acids may include, but are not limited to, alkyl sulfonic acids, aryl sulfonic acids, and sulfonic acids of alkyl succinates (e.g. see WO 2007/130069). The charge director can impart a negative charge or a positive charge on the resin-containing particles of an electrostatic ink composition.

The charge director can comprise a sulfosuccinate moiety of the general formula [R₁—O—C(O)CH₂CH(SO₃⁻)C(O)—O—R₂], where each of R₁ and R₂ is an alkyl group. In some examples, the charge director comprises nanoparticles of a simple salt and a sulfosuccinate salt of the general formula MAₙ, wherein M is a metal, n is the valence of M, and A is an ion of the general formula [R₁—O—C(O)CH₂CH(SO₃⁻)C(O)—O—R₂], where each of R₁ and R₂ is an alkyl group, or other charge directors as found in WO2007130069, which is incorporation herein by reference in its entirety. As described in WO2007130069, the sulfosuccinate salt of the general formula MAₙ is an example of a micelle forming salt. The charge director may be substantially free or free of an acid of the general formula HA, where A is as described above. The charge director may comprise micelles of said sulfosuccinate salt enclosing at least some of the nanoparticles. The charge director may comprise at least some nanoparticles having a size of 200 nm or less, in some examples 2 nm or more. As described in WO2007130069, simple salts are salts that do not form micelles by themselves, although they may form a core for micelles with a micelle forming salt. The ions constructing the simple salts are all hydrophilic. The simple salt may comprise a cation selected from the group consisting of Mg, Ca, Ba, NH₄, tert-butyl ammonium, Li⁺, and Al⁺³, or from any sub-group thereof. The simple salt may comprise an anion selected from the group consisting of SO₄²⁻, PP³⁻, NO₃⁻, HPO₄²⁻, CO₃²⁻, acetate, trifluoroacetate (TFA), Cl⁻, Bf, F⁻, ClO₄⁻, and TiO₃⁴⁻, or from any sub-group thereof. The simple salt may be selected from CaCO₃, Ba₂TiO₃, Al₂(SO₄), A1(NO₃)₃, Ca₃(PO₄)₂, BaSO₄, BaHPO₄, Ba₂(PO₄)₃, CaSO₄, (NH₄)₂CO₃, (NH₄)₂SO₄, NH₄OAc, Tert-butyl ammonium bromide, NH₄NO₃, LiTFA, Al₂(SO₄)₃, LiClO₄ and LiBF₄, or any sub-group thereof. The charge director may further comprise basic barium petronate (BBP).

In the formula [R₁—O—C(O)CH₂CH(SO₃⁻)C(O)—O—R₂], in some examples, each of R₁ and R₂ is an aliphatic alkyl group. In some examples, each of R₁ and R₂ independently is a C₆₋₂₅ alkyl. In some examples, said aliphatic alkyl group is linear. In some examples, said aliphatic alkyl group is branched. In some examples, said aliphatic alkyl group includes a linear chain of more than 6 carbon atoms. In some examples, R₁ and R₂ are the same. In some examples, at least one of R₁ and R₂ is C₁₃H₂₇. In some examples, M is Na, K, Cs, Ca, or Ba. The formula [R₁—O—C(O)CH₂CH(SO₃⁻)C(O)—O—R₂] and/or the formula MAₙ may be as defined in any part of WO2007130069.

The charge director may comprise (i) soya lecithin, (ii) a barium sulfonate salt, such as basic barium petronate (BPP), and (iii) an isopropyl amine sulfonate salt. Basic barium petronate is a barium sulfonate salt of a 21-26 hydrocarbon alkyl, and can be obtained, for example, from Chemtura. An example isopropyl amine sulphonate salt is dodecyl benzene sulfonic acid isopropyl amine, which is available from Croda.

The charge director can constitute about 0.001% to 20%, in some examples 0.01 to 20% by weight, in some examples 0.01 to 10% by weight, in some examples 0.01 to 1% by weight of the solids of the electrostatic ink composition. The charge director can constitute about 0.001 to 0.15% by weight of the solids of the electrostatic ink composition, in some examples 0.001 to 0.15%, in some examples 0.001 to 0.02% by weight of the solids of the electrostatic ink composition. In some examples, the charge director imparts a negative charge on the electrostatic ink composition. The particle conductivity may range from 50 to 500 pmho/cm, in some examples from 200-350 pmho/cm.

### Charge Adjuvant

The electrostatic ink composition and the electrostatic ink (e.g. the first, second, third and/or fourth electrostatic ink) as described herein can include a charge adjuvant. A charge adjuvant may be present with a charge director, and may be different to the charge director, and act to increase and/or stabilise the charge on particles, e.g. resin-containing particles, of an electrostatic ink composition. The charge adjuvant can include, but is not limited to, barium petronate, calcium petronate, Co salts of naphthenic acid, Ca salts of naphthenic acid, Cu salts of naphthenic acid, Mn salts of naphthenic acid, Ni salts of naphthenic acid, Zn salts of naphthenic acid, Fe salts of naphthenic acid, Ba salts of stearic acid, Co salts of stearic acid, Pb salts of stearic acid, Zn salts of stearic acid, Al salts of stearic acid, Cu salts of stearic acid, Fe salts of stearic acid, metal carboxylates (e.g. Al tristearate, Al octanoate, Li heptanoate, Fe stearate, Fe distearate, Ba stearate, Cr stearate, Mg octanoate, Ca stearate, Fe naphthenate, Zn naphthenate, Mn heptanoate, Zn heptanoate, Ba octanoate, Al octanoate, Co octanoate, Mn octanoate, and Zn octanoate), Co lineolates, Mn lineolates, Pb lineolates, Zn lineolates, Ca oleates, Co oleates, Zn palmirate, Ca resinates, Co resinates, Mn resinates, Pb resinates, Zn resinates, AB diblock co-polymers of 2-ethylhexyl methacrylate-co-methacrylic acid calcium, and ammonium salts, co-polymers of an alkyl acrylamidoglycolate alkyl ether (e.g. methyl acrylamidoglycolate methyl ether-co-vinyl acetate), and hydroxy bis(3,5-di-tert-butyl salicylic) aluminate monohydrate. In some examples, the charge adjuvant is aluminum di and/or tristearate and/or aluminum di and/or tripalmitate.

The charge adjuvant can constitute about 0.1 to 5% by weight of the solids of the electrostatic ink composition. The charge adjuvant can constitute about 0.5 to 4% by weight of the solids of the electrostatic ink composition. The charge adjuvant can constitute about 1 to 3% by weight of the solids of the electrostatic ink composition.

The electrostatic ink composition and the electrostatic ink as described herein (e.g. the first, second, third and/or fourth electrostatic ink) may further comprise a colorant. As described herein, an image layer may be disposed on or between any of the other layers, for example between the light-emitting layer and either of the first or second electrodes, or between the light-emitting layer and, if present, the dielectric layer, and the image layer may comprising a fourth electrostatic ink, e.g. comprising a thermoplastic resin and a colorant, e.g. a pigment; the image layer may not comprise an electroluminescent material, and may therefore have been printed from a fourth electrostatic ink composition, which may be a liquid electrostatic ink composition, comprising chargeable particles of the resin and the colourant, e.g. a pigment, which may be dispersed in, e.g. suspended in, a liquid carrier. The colorant may be selected from a pigment, dye and a combination thereof. The colorant may be transparent, unicolor or composed of any combination of available colors. The colorant may be selected from a cyan colorant, a yellow colorant, a magenta colorant and a black colorant. The electrostatic ink composition may comprise a plurality of colorants. The electrostatic ink composition may comprise a first colorant and second colorant, which are different from one another. Further colorants may also be present with the first and second colorants. The electrostatic ink composition may comprise first and second colorants where each is independently selected from a cyan colorant, a yellow colorant, a magenta colorant and a black colorant. In some examples, the first colorant comprises a black colorant, and the second colorant comprises a non-black colorant, for example a colorant selected from a cyan colorant, a yellow colorant and a magenta colorant. The colorant may be selected from a phthalocyanine colorant, an indigold colorant, an indanthrone colorant, a monoazo colorant, a diazo colorant, inorganic salts and complexes, dioxazine colorant, perylene colorant, anthraquinone colorants, and any combination thereof.

The second electrostatic ink may comprise a white pigment, which may be in the form of white pigment particles. In some examples, the white pigment may comprise a material selected from TiO₂, calcium carbonate, zinc oxide, and mixtures thereof, for example, the pigment may consist essentially of TiO₂. In some examples the pigment particle may be comprise an alumina-TiO₂ pigment. A form for the TiO₂ may be selected from among rutile, anatase, brookite, and mixtures thereof, for example, the form may consist of rutile. The rutile form of TiO₂ exhibits the highest refractive index among the other forms of TiO₂ and the other listed pigments. All other parameters of inks being the same, the highest refractive index yields the highest opacity. Examples of pigment particles include Sachtleben R405 from Sachtleben, and Ti-Pure® R900 from DuPont.

### Liquid Carrier

The electrostatic ink composition (e.g. for forming the first, second, third and/or fourth electrostatic ink in printed form) may be a liquid electrostatic ink composition, and comprise a liquid carrier and particles comprising the resin suspended therein. In some examples, the electrostatic ink composition comprises a carrier liquid. In some examples, particles comprising the resin and, if present, the pigment, are suspended or dispersed in the liquid carrier, which may also be termed a carrier liquid. In the particles, the resin may encapsulate, partially or completely, a pigment, which may be as described herein. Generally, the carrier liquid can act as a dispersing medium for the other components in the electrostatic ink. For example, the carrier liquid can comprise or be a hydrocarbon, silicone oil, vegetable oil, etc. The carrier liquid can include, but is not limited to, an insulating, non-polar, non-aqueous liquid that is used as the medium for toner particles. The carrier liquid can include compounds that have a resistivity in excess of about 10⁹ ohm-cm. The carrier liquid may have a dielectric constant below about 5, in some examples below about 3. The carrier liquid can include, but is not limited to, hydrocarbons. The hydrocarbon can include, but is not limited to, an aliphatic hydrocarbon, an isomerized aliphatic hydrocarbon, branched chain aliphatic hydrocarbons, aromatic hydrocarbons, and combinations thereof. Examples of the carrier liquids include, but are not limited to, aliphatic hydrocarbons, isoparaffinic compounds, paraffinic compounds, dearomatized hydrocarbon compounds, and the like. In particular, the carrier liquids can include, but are not limited to, Isopar-G™, Isopar-H™, Isopar-L™, Isopar-M™, Isopar-K™, Isopar-V™, Norpar 12™, Norpar 13™, Norpar 15™, Exxol D40™, Exxol D80™, Exxol D100™, Exxol D130™, and Exxol D140™ (each sold by EXXON CORPORATION); Teclen N-16™, Teclen N-20™, Teclen N-22™, Nisseki Naphthesol L™, Nisseki Naphthesol M™, Nisseki Naphthesol H™, #0 Solvent L™, #0 Solvent M™, #0 Solvent H™, Nisseki Isosol 300™, Nisseki Isosol 400™, AF-4™, AF-5™, AF-6™ and AF-7™ (each sold by NIPPON OIL CORPORATION); IP Solvent 1620™ and IP Solvent 2028™ (each sold by IDEMITSU PETROCHEMICAL CO., LTD.); Amsco OMS™ and Amsco 460 (each sold by AMERICAN MINERAL SPIRITS CORP.); and Electron, Positron, New II, Purogen HF (100% synthetic terpenes) (sold by ECOLINK™).

The carrier liquid can constitute about 20% to 99.5% by weight of the electrostatic ink composition, in some examples 50% to 99.5% by weight of the electrostatic ink composition. The carrier liquid may constitute about 40 to 90% by weight of the electrostatic ink composition. The carrier liquid may constitute about 60% to 80% by weight of the electrostatic ink composition. The carrier liquid may constitute about 90% to 99.5% by weight of the electrostatic ink composition, in some examples 95% to 99% by weight of the electrostatic ink composition.

The printed electrostatic ink may be substantially free from carrier liquid. In an electrostatic printing process and/or afterwards, the carrier liquid may be removed, e.g. by an electrophoresis processes during printing and/or evaporation, such that substantially only solids are transferred to a substrate, e.g. the first or second electrode, or a dielectric layer thereon. Substantially free from carrier liquid may indicate that the printed electrostatic ink contains less than 5 wt % carrier liquid, in some examples, less than 2 wt % carrier liquid, in some examples less than 1 wt % carrier liquid, in some examples less than 0.5 wt % carrier liquid. In some examples the printed electrostatic ink is free from carrier liquid.

The electrostatic ink composition (for the first, second, third and/or fourth electrostatic ink) may include an additive or a plurality of additives. The additive or plurality of additives may be added at any stage of the method. The additive or plurality of additives may be selected from a wax, a surfactant, biocides, organic solvents, viscosity modifiers, materials for pH adjustment, sequestering agents, preservatives, compatibility additives, emulsifiers and the like. The wax may be an incompatible wax. As used herein, “incompatible wax” may refer to a wax that is incompatible with the resin. Specifically, the wax phase separates from the resin phase upon the cooling of the resin fused mixture on a print substrate during and after the transfer of the ink film to the print substrate, e.g. from an intermediate transfer member, which may be a heated blanket.

The present disclosure provides, in a fourth aspect, a method of making a light-emitting electrochemical cell, the method comprising:
electrophotographically printing, using an electrostatic ink comprising chargeable particles comprising an electroluminescent material having a coating of a thermoplastic resin thereon, a light-emitting layer on a first electrode or a second electrode, or a dielectric insulating layer, which may be disposed on the first or second electrode, and then on an opposing side from the first or second electrode, disposing the other of the first and second electrodes, to form a light-emitting electrochemical cell comprising
the first electrode and the second electrode;
the light-emitting layer disposed between the first and second electrodes and comprising a printed electrostatic ink comprising the thermoplastic resin having dispersed therein an electroluminescent material,
optionally wherein a dielectric insulating layer is disposed between the light-emitting layer, and the first or the second electrode. In some examples, the first and/or second electrodes may be printed, e.g. in an electrophotographical printing process using an electrostatic ink, which may be a liquid electrostatic ink, comprising electrically conductive particles. In some examples, if present, the dielectric insulating layer may be printed on the first or second electrode or both of the first and second electrodes,

and comprising a printed electrostatic ink comprising a thermoplastic resin having dispersed therein an electroluminescent material e.g. in an electrophotographical printing process using an electrostatic ink, which may be a liquid electrostatic ink, which may or may not comprise pigmented particles (without pigment particles, it may be a clear or transparent layer, and may be disposed on a transparent electrode); with pigment particles, e.g. white particles, it may be an opaque layer, and, in some examples, disposed on an opaque electrode.

The electrostatic or electrophotographic printing using an electrostatic ink composition as described herein may involve:
forming a latent electrostatic image on a surface;
contacting the surface with the electrostatic ink composition comprising particles comprising the thermoplastic resin, such that at least some of the particles adhere to the surface to form a developed toner image on the surface, and transferring the toner image to a substrate, in some examples, via an intermediate transfer member; the substrate may be any of the electrodes or layers described herein. During the printing, the particles comprising the thermoplastic resin coalesce to form on the substrate a layer of the thermoplastic resin having dispersed therein any pigment that was present in the resin-containing particles (e.g. the electroluminescent material).

The surface on which the latent electrostatic image is formed may be on a rotating member, e.g. in the form of a cylinder. The surface on which the latent electrostatic image is formed may form part of a photo imaging plate (PIP). The intermediate transfer member may be a rotating flexible member, which may be heated, e.g. to a temperature of from 80 to 130° C.

### EXAMPLES

The following illustrates examples of a light-emitting electrochemical cell, electrostatic compositions, methods of making them and related aspects described herein. Thus, these examples should not be considered to restrict the present disclosure, but are merely in place to teach how to make examples of compositions of the present disclosure.

A light-emitting electrochemical cell was produced that was as schematically illustrated in FIG. 2. As shown in FIG. 2, the light-emitting electrochemical cell comprising a first electrode 101 and a second electrode 104 and a light-emitting layer 103 disposed between the first and second electrodes. In this example, the first electrode is an opaque electrode, e.g. a carbon or metallic (e.g. copper) electrode (this may be an electrically conductive printed electrostatic ink) and the second electrode is a transparent electrode (e.g. an indium tin oxide electrode). The light-emitting layer 103 comprises a printed electrostatic ink comprising a thermoplastic resin having dispersed therein an electroluminescent material, as described in more detail below. Light emitted from the light-emitting layer 103 is shown with arrows pointing down the page, denoted with an ‘L’. In this embodiment, a dielectric insulating layer 102 is disposed between the light-emitting layer, and the first electrode. The dielectric layer may comprise a second printed electrostatic ink comprising a thermoplastic resin, and a white pigment. The second electrode is disposed upon a transparent substrate 105, which may be glass or a clear plastic, such as a polyethylene film, for example—this acts as a support for the second electrode.

In the example below, a doped zinc sulfide phosphor material was used (in this case, EL Phosphor-GG45 from LWB) as the electroluminescent material. The front electrode that was used was ITO coated on a PET substrate and the rear electrode was copper tape or carbon, and the insulator was transparent adhesive tape (trade name: Sellotape®), but may also be a transparent electrostatic ink, which are commercially available, i.e. an electrostatic ink for use in an electrophotographic printing process comprising chargeable particles in a liquid carrier, but lacking a pigment. The emitted color of this material is blue, Yet, the disclosure is not limited to this specific phosphor material—many other colors of electroluminescent particles are available, nor the specific metallic ink and/or the insulating di-electric layer (e.g. using an insulating electrostatic ink).

The liquid electrostatic ink used to make the printed electrostatic ink containing the electroluminescent material contained component characteristic of a liquid electrophotographic ink, e.g. the thermoplastic resin and a charge director and/or a charge adjuvant, although the electroluminescent material replaced the pigment (typically a cyan, magenta, yellow of black pigment) that would normally be used in such an ink. However, the liquid electrostatic ink was produced in a process that is not conventionally used to create such an ink. As described below, trying to create the electroluminescent ink using a conventional process was not successful.

### Preparing the Electrostatic Ink Containing the Electroluminescent Material

EL Ink Preparation:

Resins (35 parts of the solids of ink composition):
Nucrel®699 (Dupont)—80 wt % of the 35 parts
A-C 5120 (Honeywell)—20% of the 35 parts
(in other words, Nucrel®699: A-C 5120 wt:wt ratio is 4:1)

Electroluminescent pigment (65 parts of the solids of the ink composition):

LP6845—Zinc sulfide, activated—white color from Leuchtstoffwerke Breitungen GmbH

Further trade names for other electroluminescent pigments:
EL01/blue (Types: LP-682x)
EL01/green (Types: LP-684x)
EL01/orange (Types: LP-681x)

The electroluminescent pigment may alternatively be any other electroluminescent material described herein.

Precipitation technique: In this method, the resins at the pre-determined weight ratio were melted in isopar-L under constant mixing at 140° C. in 2L reactor. The melt process is very slow and takes an average of 2 hours. After, the resulted paste-like mixture was cooled down (cooling rate of 0.5° C./minute) to 80° C. under constant mixing. After, 65 wt % LP6845 (to total mass) was added under high-shear (7K, rpm, although this may be from 4K rpm to 8 K rpm, e.g. 5K rpm, 6K rpm) and constant mixing (60 RPM); at the point that the pigment was added, the temperature was at or above the cloud point of the resins (in this case at or above 80° C.). The high-shear mixing was found effective for the efficient dispersion of LP6845 in the highly-viscous resin melt. The high-shear mixing causes some rise in the melt-temperature and special care ought to be taken to avoid exceeding 80° C. After 30 minutes, the high-shear mixing is ceased and cooling is continued at a rate of 3° C./hour under constant mixing, e.g. by stirring, e.g. at 40 rpm to 100 rpm. At 60° C., the melt turns into a white paste. Finally, the paste is cooled down to 40° C. at 0.5° C./minute and discharged.

Paste Post treatment: The paste including the LP6845 pigment, after it has been discharged from the mixer, had a very low particle conductivity˜10 pmho.

To increase Particle conductivity, a post treatment in S1 ceramic attritor was carried out—aluminium stearate (VCA, available from Sigma Aldrich™) (1 wt %) was added to the paste included the LP6845 (99% wt %).

It was found that a relatively light grinding (compared to some grinding processes used to produce liquid electrostatic inks, particularly those used for inks containing black, magenta, yellow or cyan pigments) avoided damage of the pigment and a loss in its electroluminescent properties. Accordingly, the post treatment grinding in the S1 attritor was carried out at a low revolution rate of 120 RPM for 1 hour at 35° C. A charge director was also added (NCD or natural charge director, which comprises three components—natural soya lecithin in phospholipids and fatty acids, BBP (basic barium petronate i.e. a barium sulfonate salt of a 21-26 hydrocarbon alkyl, supplied by Chemtura), and GT (dodecyl benzene sulfonic acid isopropyl amine, supplied by Croda). The composition being 6.6 wt % KT, 9.8 wt % BBP and 3.6 wt % GT, balance 80% Isopar. The charge director was added in an amount of about 20 mg NCD per gr of solids of the electrostatic ink composition

The particle conductivity after the post treatment is between 130 to 160 pmho. From the latest treatment, an ink is prepared. Particle conductivity is defined as the high field conductivity minus the low field conductivity, e.g. as described in, for example WO2017/063719.

The resultant ink, when used in a device as shown in FIG. 2 showed strong electroluminescence.

In a comparative example, the same components were combined to form an electrostatic ink, except, instead of the precipitation method of forming particles of the luminescent material having the resin coating thereon, an initial grinding process was used (with the particles of electroluminescent material being ground in a ball mill with resin and the isopar and the VCA)—this involved grinding for a number of hours (e.g. about 8-10 hours, grinding at 250 RPM or more, and at a temperature of 50° C. or more), as may often be done when forming an electrostatic ink with a cyan, magenta, yellow or black pigment. The ink that resulted from this method, when used in a device as shown in FIG. 2, showed little, if any, electroluminescence. While not being bound by theory, it may be that the CuS on the phosphor surface are broken apart by continued grinding, eventually reducing the effectiveness of the CuS-induced electric field enhancement.

### Making the Electroluminescent Device

An electroluminescent device in accordance with FIG. 2 was made as follows. In the following, the printing was carried out using a liquid electrophotographic printing process using in 7X00 Sheet fed HP indigo presses.

First, a substrate was obtained. This was a PET layer coated with ITO G4303 (i.e. a PET transparent substrate having an indium tin oxide layer thereon, with the latter acting as a transparent electrode), resistance of 100 ohm/sq, film thickness 125 um produced by Multek. In FIG. 2, layer 105 is the PET layer. Layer 104 is the ITO layer.

The slide was cleaned with IPA, and corona activated before inserting the press.

The electrostatic ink containing the electroluminescent material was printed directly onto the ITO layer of the substrate. The ink (WD:5% NVS; LFC=75 pmho) was printed with the printing working points:
DRV=500 V
ELV=1000 V

The number of separations (single printed layers) of the ink was 6. This printed ink is layer 103 in FIG. 2. (WD indicates working dispersion, i.e. the ink used in the printing press—this was diluted to 5 wt % non-volatile solids (i.e. ‘5% NVS’) with isopar-L, ‘LFC’ indicates low field charge, as defined in, for example, WO20171063719)

The insulating dielectric layer was also electrostatically printed onto the layer of electrostatic ink containing the electroluminescent material. The insulating layer was a HP electrophotographic premium white ink (WD:5% NVS; LFC=80 pmho) and printed using a premium white working point using premium white ink file. The insulating dielectric layer is layer 102 in FIG. 2.

The number of insulating di electric separations was 10.

The rear (opaque) electrode conductive layer was a copper-containing layer. It was printed using copper based conductive electrostatic ink (WD=5% Nvs, LFC=70 pmho), was consecutively printed with the experimental metallic working point parameters using a suitable binary ink developer, it was printed in a smaller patch in comparison to the insulator to avoid contact with the front electrode (ITO). The copper-containing layer is layer 101 in FIG. 2.

The number of conductive layers printed was 10.

This produced a device as shown schematically in FIG. 2.

To effect electroluminescence, an AC voltage was applied. A DC-AC converter was used (ERG LPS05-3-4p convert from 9V to 100V); this was connected to a 9V battery for the DC power supply. The converter was connected to the device according to diagram above (FIG. 2)—in this figure, the AC power supply is denoted by the AC in the circle, and the connectors to the first and second electrodes by 106.

Photometric values from typical screen-printed test lamps operated at 100V, 400 Hz.

The electrostatic ink containing the electroluminescent material can be printed in a block or in any desired printed form, including, but not limited to, pictures, patterns, letters, numbers and symbols. In the test above, the letters ‘LAMPA HP’ and rectangular block were printed using the electrostatic ink containing the electroluminescent material. All the letters of ‘LAMPA HP’ and the rectangular block lit up from the electroluminescence when the AC voltage was applied to the first and second electrodes.

While the light-emitting electrochemical cells, electrostatic ink compositions, methods and related aspects have been described with reference to certain examples, it will be appreciated that various modifications, changes, omissions, and substitutions can be made. It is intended, therefore, that the electrostatic ink compositions, methods and related aspects be limited only by the scope of the following claims. Unless otherwise stated, the features of any dependent claim can be combined with the features of any of the other dependent claims, and any other independent claim.

1. A light-emitting electrochemical cell comprising:
a first electrode and a second electrode;
a light-emitting layer disposed between the first and second electrodes and comprising a printed electrostatic ink comprising a thermoplastic resin having dispersed therein an electroluminescent material.

2. A light-emitting electrochemical cell according to claim 1, wherein the electroluminescent material is selected from an inorganic electroluminescent material and organic electroluminescent material.

3. A light-emitting electrochemical cell according to claim 2, wherein the inorganic electroluminescent material is selected from a doped zinc sulfide, a semi-conductor comprising a Group Ill element and a Group V element (e.g. selected from indium phosphide, gallium arsenide and gallium nitride), a doped diamond and an organic semiconductor.

4. A light-emitting electrochemical cell according to claim 3, wherein the doped zinc sulfide is includes a dopant selected from copper, manganese, and silver.

5. A light-emitting electrochemical cell according to claim 1, wherein the resin comprises a polymer having acidic side groups.

6. A light-emitting electrochemical cell according to claim 1, wherein the resin comprises a co-polymer of copolymers of ethylene and an ethylenically unsaturated acid of either methacrylic acid or acrylic acid.

7. A light-emitting electrochemical cell according to claim 1, wherein a dielectric insulating layer is disposed between the light-emitting layer, and the first or the second electrode, and the dielectric layer comprises a second printed electrostatic ink comprising a thermoplastic resin.

8. A light-emitting electrochemical cell according to claim 7, wherein the second electrode is a transparent electrode, the dielectric insulating layer is disposed between the light-emitting layer and the first electrode.

9. A light-emitting electrochemical cell according to claim 8, wherein the second printed electrostatic ink comprising a thermoplastic resin comprises a white pigment, and the first electrode is an opaque electrode comprising a third printed electrostatic ink comprising a thermoplastic resin and an electrically conductive pigment.

10. A method of making an electrostatic ink, the method comprising:
providing a carrier fluid (i) in which is dispersed a molten or a dissolved thermoplastic polymer resin and (ii) containing particles of an electroluminescent material suspended therein;
effecting precipitation of the polymer resin from the carrier fluid onto the electroluminescent material to form particles comprising the electroluminescent material with a coating comprising the thermoplastic resin in solid form thereon.

11. The method according to claim 10, wherein the electroluminescent particles suspended in the carrier fluid have a particle size, D50, of from 10 to 40 microns and the method does not substantially reduce the particle size of the electroluminescent particles.

12. An electrostatic ink comprising:
chargeable particles comprising an electroluminescent material having a coating of a thermoplastic resin thereon.

13. The electrostatic ink according to claim 12, wherein the electroluminescent material is an inorganic electroluminescent material selected from a doped zinc sulfide, a semi-conductor comprising a Group Ill element and a Group V element, e.g. selected from indium phosphide, gallium arsenide and gallium nitride, a doped diamond and an organic semiconductor.

14. The electrostatic ink according to claim 13, wherein (i) the thermoplastic resin comprises a co-polymer of copolymers of ethylene and an ethylenically unsaturated acid of either methacrylic acid or acrylic acid and/or (ii) the ink is a liquid electrostatic ink, and chargeable particles are suspended in a liquid carrier and the ink further comprises a charge director and/or a charge adjuvant.

15. The electrostatic ink according to claim 12, wherein the ink is formable in the method according to claim 10.
